(19) United States
(12) Patent Application Publication
(10) Pub. No.: US 2019/0280129 A1
(43) Pub. Date: Sep. 12, 2019

(54) HIGH VOLTAGE SCHOTTKY DIODE

(71) Applicant: CYSTECH ELECTRONICS CORP., New Taipei City (TW)

(72) Inventors: HSIN-YU HSU, HSINCHU CITY (TW); CHEN-HUANG WANG, HSINCHU COUNTY (TW)

(21) Appl. No.: 16/296,128

(22) Filed: Mar. 7, 2019

(30) Foreign Application Priority Data
Mar. 9, 2018 (TW) 107108139

(51) Int. Cl. H01L 29/872; H01L 29/47; H01L 29/24; H01L 21/02

(52) U.S. Cl. CPC H01L 29/8725; H01L 21/02573; H01L 29/24; H01L 29/47

(57) ABSTRACT

A high voltage Schottky diode applied to a high voltage range includes a substrate, an epitaxy layer, doped regions, trenches and a metal layer. The epitaxy layer is disposed on the substrate. The doped regions are disposed in the epitaxy layer. The trenches are disposed on the doped regions in a spaced manner and are in the epitaxy layer. Each trench has a trench oxide layer and a semiconductor layer. Each trench oxide layer is formed on a bottom of each trench and the side of each trench. Each semiconductor layer fills each trench. The metal layer is disposed on the epitaxy layer and become a Schottky contact with the epitaxy layer. Since each depth of the plurality of trenches is micrometer-sized and there is the configuration of the trench oxide layers, this high voltage Schottky diode can operate successfully in a high voltage range.

### CROSS-REFERENCE TO RELATED APPLICATION

This application claims the benefit of Taiwan Patent Application No. 107108139, filed on Mar. 9, 2018, in the Taiwan Intellectual Property Office, the disclosure of which is incorporated herein in its entirety by reference.

### BACKGROUND OF THE INVENTION

### 1. Field of the Invention

The present invention relates to a Schottky diode, more particularly to a high voltage Schottky diode which has a trench structure and is able to withstand high voltage.

### 2. Description of the Related Art

With the advancement of electronic technology and the miniaturization trend of electronic products, more and more electronic components are being produced by integrated circuit (IC) processes. However, IC-type electronic components need to consider many issues, such as issues of withstanding voltage, handling interference, or anti-noise considerations. Because the power supply circuit is configured to receive a high voltage input in the electronic components applied to the power supply circuits, the IC type electronic components may be burned by the high voltage input, which in turn may cause a fault of the power supply circuit. This is a main reason that it is hard to reduce the size of the power supply circuit.

Furthermore, a diode plays a very important role in the power supply circuit. Because of characteristics of conduction in forward bias and cutoff in reverse bias, the diode is used to perform rectification for outputting a stable voltage in a power supply circuit. With the miniaturization trend of electronic products, the diodes are gradually implemented and produced by integrated circuits. However, when the power supply circuit receives high voltage, the IC-type diodes would be burned by the high voltage.

Accordingly, the inventor of the present invention has designed a high voltage Schottky diode and a transfer method thereof to overcome deficiencies in terms of current techniques so as to enhance the implementation and application in industries.

### SUMMARY OF THE INVENTION

An objective of the present invention is to provide a high voltage Schottky diode for solving the conventional problems.

In order to achieve the objective, the present invention provides a high voltage Schottky diode which is applicable to a high voltage range. The high voltage Schottky diode comprises a substrate, an epitaxial layer, a plurality of doped regions, a plurality of trenches, and a metal layer. The epitaxial layer is disposed on the substrate. The plurality of doped regions are disposed in the epitaxial layer. The plurality of trenches are respectively arranged on the plurality of doped regions in a spaced manner and are disposed in the epitaxial layer. Each of plurality of trenches is provided with a trench oxide layer formed at a bottom and side walls thereof and a semiconductor layer filling therein. The metal layer is disposed on the epitaxial layer. The metal layer and the epitaxial layer form a Schottky contact.

In a preferred embodiment of the present invention, the substrate is a silicon substrate, each of the plurality of trench oxide layers is formed by silicon oxide, and each of the plurality of semiconductor layers is formed by polysilicon.

In a preferred embodiment of the present invention, each of plurality of trenches comprises a trench nitride layer formed between the trench oxide layer and the semiconductor layer, and the trench nitride layer is formed by silicon nitride.

In a preferred embodiment of the present invention, the trench oxide layer is disposed between the trench nitride layer and the semiconductor layer, and the trench nitride layer is disposed between the two trench oxide layers.

In a preferred embodiment of the present invention, each of the plurality of trenches has a depth of between 7 microns and 15 microns.

In a preferred embodiment of the present invention, the epitaxial layer is P-type, and the plurality of doped regions are N-type.

In a preferred embodiment of the present invention, the epitaxial layer is N-type, and the plurality of doped regions are P-type.

In a preferred embodiment of the present invention, the high voltage range is from 200 volts to 800 volts.

According to above contents, the high voltage Schottky diode of the present invention has a micrometer-sized configuration for the trenches, trench oxide layers, and trench nitride layers, so that the high voltage Schottky diode of the present invention can still operate normally under a high voltage range. The Schottky diode may be applied to a power supply circuit receiving a high voltage input, thereby achieving the purpose of power supply circuit miniaturization.

### BRIEF DESCRIPTION OF THE DRAWINGS

The structure, operating principle and effects of the present invention will be described in detail by way of various embodiments which are illustrated in the accompanying drawings.

FIG. 1 is a structural diagram of a first embodiment of a high voltage Schottky diode of the present invention.

FIG. 2 is a voltage-versus-current diagram of a first embodiment of a high voltage Schottky diode of the present invention.

FIG. 3 is a structural diagram of a second embodiment of a high voltage Schottky diode of the present invention.

FIG. 4 is a structural diagram of a third embodiment of a high voltage Schottky diode of the present invention.

### DETAILED DESCRIPTION OF THE PREFERRED EMBODIMENTS

The following embodiments of the present invention are herein described in detail with reference to the accompanying drawings. These drawings show specific examples of the embodiments of the present invention. It is to be acknowledged that these embodiments are exemplary implementations and are not to be construed as limiting the scope of the present invention in any way. Further modifications to the disclosed embodiments, as well as other embodiments, are also included within the scope of the appended claims. These embodiments are provided so that this disclosure is thorough and complete, and fully conveys the inventive concept to those skilled in the art. Regarding the drawings, the relative proportions and ratios of elements in the drawings may be exaggerated or diminished in size for the sake of clarity and convenience. Such arbitrary proportions are only illustrative and not limiting in any way. The same reference numbers are used in the drawings and description to refer to the same or like parts.

It is to be acknowledged that although the terms ‘first’, ‘second’, ‘third’, and so on, may be used herein to describe various elements, these elements should not be limited by these terms. These terms are used only for the purpose of distinguishing one component from another component. Thus, a first element discussed herein could be termed a second element without altering the description of the present disclosure. As used herein, the term “or” includes any and all combinations of one or more of the associated listed items.

It will be acknowledged that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present.

In addition, unless explicitly described to the contrary, the word “comprise” and variations such as “comprises” or “comprising”, will be acknowledged to imply the inclusion of stated elements but not the exclusion of any other elements.

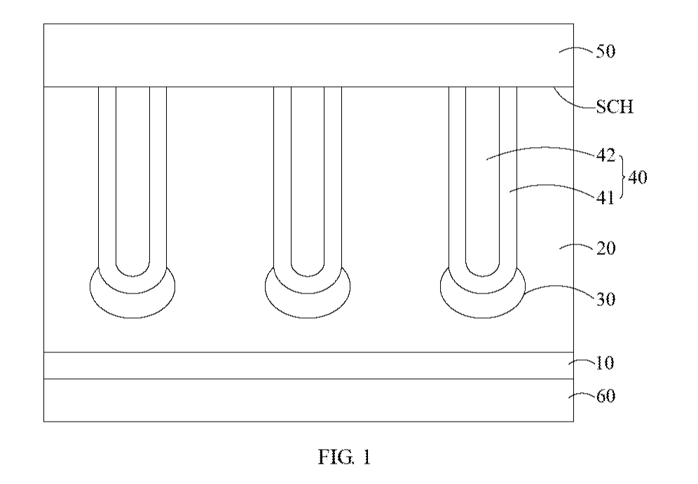

Please refer to FIG. 1, which is a structural diagram of a first embodiment of a high voltage Schottky diode of the present invention. In the embodiment, a high voltage Schottky diode of the present invention can comprise a substrate 10, an epitaxial layer 20, a plurality of doped regions 30, a plurality of trenches 40 and a metal layer 50. The substrate 10 may be a silicon substrate. The epitaxial layer 20 is disposed on the substrate 10 and may be P-type. The plurality of doped regions 30 are disposed inside the epitaxial layer 20 and may be N-type. The plurality of trenches 40 are arranged on the doped region 30 in a spaced manner, and disposed in the epitaxial layer 20. Each trench 40 may be provided with a trench oxide layer 41 and a semiconductor layer 42. The trench oxide layer 41 is formed at a bottom and side walls of each trench 40, and the semiconductor layer 42 fills each trench 40. The trench oxide layer 41 may be formed by silicon oxide, and the semiconductor layer 42 may be formed by polysilicon. The metal layer 50 is disposed on the epitaxial layer 20. The metal layer 50 and the epitaxial layer 20 form a Schottky contact SCH. An electrode layer 60 is disposed under the substrate 10 to serve as a negative electrode, and the metal layer 50 serves as a positive electrode. When a voltage is applied to the high voltage Schottky diode of the present invention, the metal layer 50 and the epitaxial layer 20 can form the Schottky contact SCH, and the high voltage Schottky diode can serve as a rectifying component of a high voltage power supply circuit.

Each trench 40 has a depth of between 7 microns and 15 microns, and each trench 40 is provided with the trench oxide layer 41 which is formed by silicon oxide and has a very high resistance and is riot easily conductive. For this purpose, the high voltage Schottky diode of the invention can withstand a high voltage range of 200 volts to 800 volts, and the depth of each trench 40 can be adjusted according to requirements in the voltage specification of the electronic components. Hence, the high voltage Schottky diode may be applied to the power supply circuit with different voltage specifications, and the high voltage Schottky diode is not burned out by high voltage. Determining an appropriate thickness of the trench oxide layer 41 is very important, because when the thickness of the trench oxide layer 41 is too thin, the high voltage Schottky diode is unable to withstand high voltage because of reduced resistance. Preferably, the thickness of the trench oxide layer 41 may be in a range of 600 nm to 1000 nm, so that the trench oxide layer 41 does not conduct easily, and the high voltage Schottky diode can withstand high voltage.

Furthermore, the plurality of doped regions 30 and the plurality of epitaxial layers 20 need to be doped at the low concentration because the high concentration doping increases conductivity. When the doped regions 30 and epitaxial layer 20 are doped at a high concentration, the high voltage Schottky diode may be burned out by high voltage because of the increased conductivity. Therefore, the plurality of doped regions 30 and the epitaxial layer 20 are doped at a low concentration to reduce the conductivity thereof, so that the high voltage Schottky diode of the present invention can withstand high voltages. Preferably, the concentration of each doped region 30 may be in a range of 10¹⁵ to 10¹⁷/cm³, the concentration of the epitaxial layer 20 may be in range of 10¹⁴ to 10¹⁶/cm³, the concentration of the substrate 10 may be 10¹⁹/cm³, and the concentration of each of the doped region 30 and epitaxial layer 20 is about 1000 times different from the concentration of the substrate 10. When a high voltage is applied to the high voltage Schottky diode of the present invention, the doped regions 30 and the epitaxial layer 20 do not conduct easily because of the low concentration thereof so that the high voltage Schottky diode of the present invention can operate normally at a high voltage.

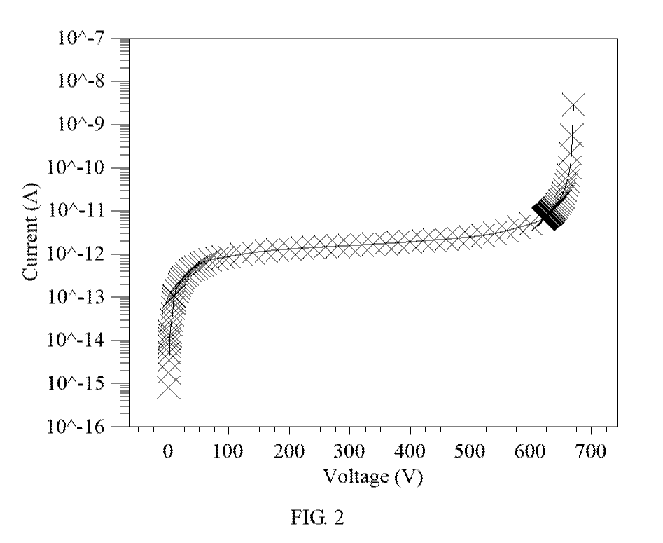

Please refer to FIG. 2, which is a voltage-versus-current diagram of a first embodiment of a high voltage Schottky diode of the present invention. FIG. 2 shows the electrical property of the Schottky diode of the first embodiment of the present invention. The measurement condition is that the high voltage is applied to the electrode layer 60, and the low voltage is applied to the metal layer 50, so that the voltage at the negative electrode is higher than the voltage at the positive electrode, and the high voltage Schottky diode of the present invention can be in a reverse bias state. As shown in FIG. 2, the reverse threshold voltage is about 625 V, indicating that the high voltage Schottky diode of the invention is able to be normally operated above 600V so as to prevent the Schottky diode from not being burned out at a high voltage.

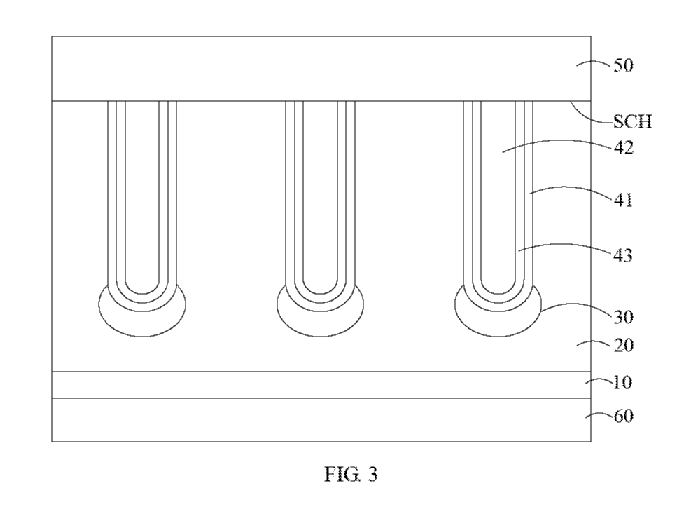

Please refer to FIG. 3, which is a structural diagram of a second embodiment of the high voltage Schottky diode of the present invention. In the present embodiment, like reference numerals designate like structures, elements, or parts throughout the specification, and the configuration is similar to aforementioned embodiment, so related descriptions are not repeated herein.

As shown in FIG. 3, a trench nitride layer 43 is disposed between the trench oxide layer 41 and the semiconductor layer 42, and the trench nitride layer 43 may be formed by the silicon nitride. A stacking order between the trench nitride layers 43 and the trench oxide layers 41 is interchangeable; in other words, the plurality of trench nitride layers 43 may be deposited in the plurality of trench 40, respectively, and next, the plurality of trench oxide layers 41 and the plurality of semiconductor layers 42 are then deposited. Since the resistance of silicon nitride is also very high, the Schottky diode having the configuration of the trench oxide layers 41 and the trench nitride layers 43 can withstand the high voltage. An electrode layer 60 is disposed under the substrate 10 to serve as a negative electrode, the metal layer 50 serves as a positive electrode. When a voltage is applied to the high voltage Schottky diode of the present invention, the Schottky contact SCH form between the metal layer 50 and the epitaxial layer 20, and the high voltage Schottky diode is able to serve as a rectifying component of a high voltage power supply circuit.

Furthermore, the epitaxial layer 20 may be N-type, the doped regions 30 may be P-type. In an embodiment, the epitaxial layer 20 may be changed to P-type and the doped region 30 may be changed to N-type upon requirements in actual application. It should be noted that the scope of the present invention is not limited to above examples.

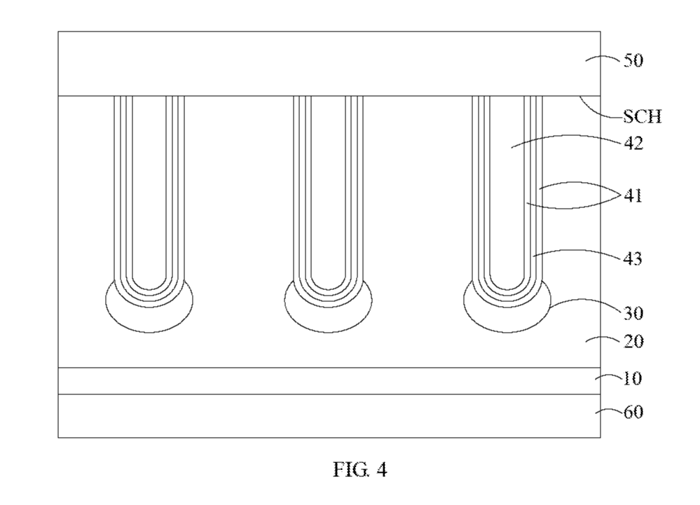

Please refer to FIG. 4, which is a structural diagram of a third embodiment of a high voltage Schottky diode of the present invention. In the present embodiment, like reference numerals designate like structures, elements, or parts throughout the specification, the configuration is similar to aforementioned embodiment, so related descriptions are not repeated herein.

As shown in FIG. 4, a trench oxide layer 41 is disposed between the trench nitride layer 43 and the semiconductor layer 42, and the trench nitride layer 43 is disposed between the two trench oxide layers 41. The configuration of the two trench oxide layers 41 and the trench nitride layer 43 can increases resistance to withstand higher voltage. Furthermore, the thicknesses of two trench oxide layers 41 and trench nitride layer 43 can be adjusted according to the voltage specifications of electronic components, so as to meet different voltage specifications of the power supply circuit, and prevent the high voltage Schottky diode of the present invention from being burned out by high voltage.

According to above-mentioned contents, the configuration of the trench oxide layers 41 and the trench nitride layers 43 is used in the high voltage Schottky diode of the present invention, so the high voltage Schottky diode of the invention can still operate normally in a high voltage range. Furthermore, according to requirements in the voltage specification of the power supply circuit, the depth of each trench 40 can be appropriately determined to meet different high voltage specifications and performs the rectification function in the power supply circuit under high voltage. As a result, the high voltage Schottky diode of the present invention has the above advantages, and using the configuration of the trench oxide layers 41 and the trench nitride layers 43 is able to achieve the purpose of operating the high voltage Schottky diode at high voltage.

The present invention disclosed herein has been described by means of specific embodiments. However, numerous modifications, variations and enhancements can be made thereto by those skilled in the art without departing from the spirit and scope of the disclosure set forth in the claims.

What is claimed is:

1. A high voltage Schottky diode, applicable to a high voltage range, comprising:
a substrate; and
an epitaxial layer disposed on the substrate;
a plurality of doped regions disposed in the epitaxial layer;
a plurality of trenches respectively disposed on the plurality of doped regions in a spaced manner, respectively, and located in the epitaxial layer, wherein each of plurality of trenches provided with a trench oxide layer formed at a bottom and side walls thereof, and a semiconductor layer filling therein; and
a metal layer disposed on the epitaxial layer, wherein the metal layer and the epitaxial layer forming a Schottky contact.

2. The high voltage Schottky diode according o claim 1, wherein the substrate is a silicon substrate, each of the plurality of trench oxide layers is formed by silicon oxide, and each of the plurality of semiconductor layers is formed by poly-silicon.

3. The high voltage Schottky diode according to claim 1, wherein each of plurality of trenches comprises a trench nitride layer formed between the trench oxide layer and the semiconductor layer, and the trench nitride layer is formed by silicon nitride.

4. The high voltage Schottky diode according to claim 3, wherein the trench oxide layer is disposed between the trench nitride layer and the semiconductor layer, and the trench nitride layer is disposed between the two trench oxide layers.

5. The high voltage Schottky diode according to claim 1, wherein a depth of each of the plurality of trenches is 7 microns to 15 microns.

6. The high voltage Schottky diode according to claim 1, wherein the epitaxial layer is P-type, and the plurality of doped regions are N-type.

7. The high voltage Schottky diode according to claim 1, wherein the epitaxial layer is N-type, and the plurality of doped regions are P-type.

8. The high voltage Schottky diode according to claim 1, wherein the high voltage range is from 200 volts to 800 volts.
